(19) United States
(12) Patent Application Publication
(10) Pub. No.: US 2025/0096195 A1
(43) Pub. Date: Mar. 20, 2025

(54) Wire Bonding Method and Apparatus

(71) Applicant: Infineon Technologies AG, Neubiberg (DE)

(72) Inventors: Stefan Tophinke, Paderborn (DE); Paul Kaiser, Arnsberg (DE); Markus Brüning, Soest (DE)

(21) Appl. No.: 18/368,251

(22) Filed: Sep. 14, 2023

(51) Int. Cl. H01L 23/00

(52) U.S. Cl. CPC H01L 24/85; H01L 24/45; H01L 24/48; H01L 24/78; H01L 2224/45147; H01L 2224/48011; H01L 2224/48091; H01L 2224/78756; H01L 2224/85136; H01L 2924/2065; H01L 2924/20651; H01L 2924/20652; H01L 2924/2076

(57) ABSTRACT

A method forming a bond wire connection includes providing a wire bonder including a bond wedge with a wire guide, and forming a wire bond loop by initially bonding a bond wire to a first bonding surface using the bond wedge, then moving the wire bonder in a loop pattern whereby the bond wire passes through the wire guide, and then bonding the bond wire to a second bonding surface using the bond wedge, wherein moving the wire bonder in the loop pattern comprises a retrograde movement whereby the wire bonder moves away from the second bonding surface, and wherein the wire guide is formed from a material with a higher material hardness than the bond wire.

### BACKGROUND

Semiconductor devices are typically provided within a package that houses and protects the dies and associated electrical connections from the exterior environment. A discrete package may include one or more semiconductor dies mounted on a metal lead frame. A power module may include several dies mounted on a power electronics carrier, e.g., DBC (direct bonded copper) substrate, IMS (insulated metal substrate) or AMB (active metal brazed) substrate, and an enclosure over the power electronics carrier. In either type of package, electrical interconnections must be made between the various components, e.g., die to lead connections, die to die connections, bond pad to bond pad connections, etc. There are various ways to form these electrical interconnections. One such way is a wire bonding technique. It would be desirable to improve the quality, performance, and cost of wire bonding.

### SUMMARY

A method of forming a bond wire connection is disclosed. According to an embodiment, the method comprises providing a wire bonder comprising a bond wedge with a wire guide, and forming a wire bond loop by initially bonding a bond wire to a first bonding surface using the bond wedge, then moving the bond wedge in a loop pattern whereby the bond wire passes through the wire guide, and then bonding the bond wire to a second bonding surface using the bond wedge, wherein moving the bond wedge in the loop pattern comprises a retrograde movement whereby the bond wedge moves away from the second bonding surface after bonding the first bond, and wherein the wire guide is formed from a material with a higher material hardness than the bond wire.

A semiconductor device is disclosed. According to an embodiment, the semiconductor device comprises a bond wire connection that forms an electrical connection of a semiconductor device, wherein the bond wire connection comprises a wire bond loop between a first bonding surface and a second bonding surface, wherein the wire bond loop is formed from a bond wire comprising copper with a diameter of between 400 μm and 500 μm, wherein a bond loop length of the wire bond loop is ≤5,500 μm, and wherein a bond loop height of the wire bond loop is ≤2,5000 μm.

### BRIEF DESCRIPTION OF THE DRAWINGS

The elements of the drawings are not necessarily to scale relative to each other. Like reference numerals designate corresponding similar parts. The features of the various illustrated embodiments can be combined unless they exclude each other. Embodiments are depicted in the drawings and are detailed in the description which follows.

FIG. 1 illustrates a wire bond loop from a bond wire connection, according to an embodiment.

FIG. 2 illustrates the tooling of a bond wedge, according to an embodiment.

FIG. 3, which includes FIGS. 3A-3D, illustrates a method of forming a wire bond loop at various stages in the movement of the bond wedge, according to an embodiment.

FIG. 4 illustrates a loop pattern followed by a bond wedge, according to an embodiment.

### DETAILED DESCRIPTION

Embodiments of a method of forming a bond wire connection and corresponding bond wire connection are disclosed herein. The bond wire connection comprises a wire bond loop between a first bonding surface and a second bonding surface. The physical attributes of the wire bond loop, specifically the relation between the bond loop height and the bond loop length, are advantageous. Conventionally when forming wire bond loops, there is a tradeoff between the minimum attainable bond loop height relative bond loop length. As the bond loop length decreases, the bond loop height must be increased to reliably effectuate the bond wire connection. The methods disclosed herein facilitate the formation of otherwise unattainably low bond loop height values relative to bond loop length. In particular, the methods comprise using a bond wedge with a wire guide that is harder than the bond wire form the wire bond loop. In addition, the methods comprise using a retrograde movement into the loop pattern wherein the bond wedge moves backwards and away from the intended subsequent bonding point. The combination of the stiffer wire guide bond wedge and retrograde movement cause a shaping of the bond wire during the loop formation that reliably creates low-profile wire bond loops.

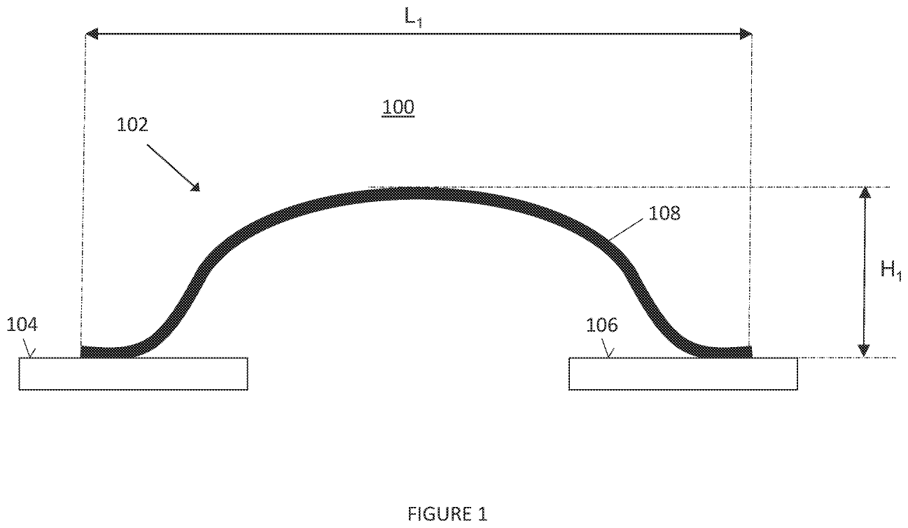

Referring to FIG. 1, a bond wire connection 100 is shown, according to an embodiment. The bond wire connection 100 forms an electrical connection of a semiconductor device. For example, the bond wire connection 100 may form an electrical connection between the structured metal pads of a circuit carrier, e.g., a PCB (printed circuit board), a DBC (direct bonded copper) substrate, IMS (insulated substrate) substrate or AMB (active metal brazed) substrate and/or may form an electrical connection between the bond pad from a semiconductor die and a circuit carrier, lead frame, or other semiconductor die. The bond wire connection 100 comprises a wire bond loop 102 between a first bonding surface 104 and a second bonding surface 106. The first bonding surface 104 and the second bonding surface 106 are metal surfaces configured to mate with a bond wire. For example, the first bonding surface 104 and the second bonding surface 106 may be provided by one or two bond pads from a semiconductor die, circuit carrier, lead frame, etc. The first bonding surface 104 and the second bonding surface 106 may be provided from metal structures that comprise and/or are plated with Cu, Ni, Ag, Au, Pd, Pt, Ni, for example. As shown, the first bonding surface 104 and the second bonding surface 106 are on the same vertical level. In other cases, the first bonding surface 104 and the second bonding surface 106 may be vertically offset from one another, e.g., in the case of a wire bond loop 102 formed between a semiconductor die and a lead frame or circuit carrier. As shown, the bond wire connection 100 comprises a single wire bond loop 102 between two metal structures that are separated from one another. In other embodiments, a bond wire connection 100 may comprise multiple wire bond loops 102, e.g., a bond wire may be affixed to a single bond pad, e.g., from a circuit carrier by multiple wire bond loops 102 to enhance mechanical attachment and/or lower electrical resistance. In that case, the first bonding surface 104 and the second bonding surface 106 can be from the same continuous metal structure.

The wire bond loop 102 is formed by a bond wire 108. The bond wire 108 comprises a low electrical resistance metal that is suitable for semiconductor device interconnection. For example, the metal bond wire 108 may comprise copper, aluminum, silver, and alloys thereof. According to an embodiment, the metal bond wire 108 is a copper bond wire 108, i.e., a bond wire 108 formed of substantially pure copper, e.g., 95% pure or 99% pure copper. A diameter of the bond wire 108 may be in the range of 25 μm and 750 μm, for example. According to an embodiment, the diameter of the bond wire 108 is in the range of 300 μm and 500 μm. In a more particular embodiment, the bond wire 108 is a copper bond wire 108 with a diameter of 400 μm, meaning that the nominal diameter value of the wire is 400 μm. The bond wire 108 may have a rounded cross-section. Other cross-sectional geometries such as rectangular geometries are possible as well.

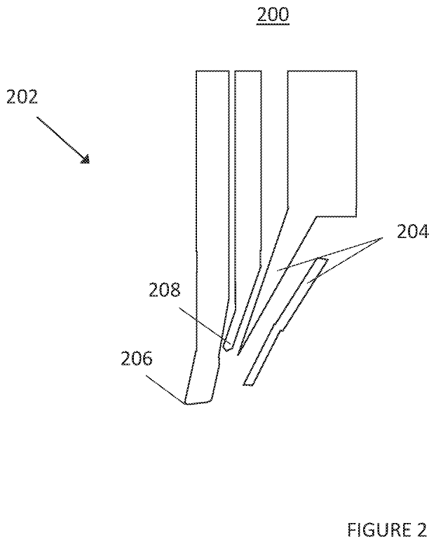

Referring to FIG. 2, a method of forming the bond wire connection 100 comprises providing a wire bonder 200. The wire bonder 200 comprises a bond wedge 202 with a wire guide 204. The bond wedge 202 may be connected to a shaft (not shown) and may be actuated by a programmable robotic mechanism. The wire guide 204 forms a channel on the bond wedge 202 that is dimensioned to retain and guide a bond wire 108 while it moves through the wire guide 204. The wire guide 204 comprises a backing (not shown) that corresponds to a bottom surface of this channel. The wire bonder 200 is configured to feed a length of bond wire 108 through the wire guide 204 such that the bond wire 108 wraps around a tip 206 of the bond wedge 202. The tip 206 can be used to apply mechanical pressure and ultrasonic energy and/or manipulate the bond wire 108. The bond wedge 202 may additionally comprise a blade 208 that is between the wire guide 204 and the tip 206 of the bond wedge 202. The blade 208 is slidable outward and is used to sever the bond wire 108 as needed.

According to an embodiment, the wire guide 204 is formed from a material with a higher material hardness than the bond wire 108. Material hardness refers to the degree to which the material irreversibly deforms in response to an applied force, i.e., the plasticity of the material. Material hardness may be measured according to the measured according to the Rockwell, Vickers, Shore, or Brinell scale. Thus, in the case that the bond wire 108 comprises, copper, aluminum, or alloys thereof, the wire guide 204 may be formed from a metal with a higher material hardness than metal which forms the bond wire 108. According to an embodiment, the wire guide 204 comprises any one or more of: Cu, Ni, Ti, Zn, Fe, and alloys thereof, wherein these metals or alloys are selected harder than the bond wire 108. In one particular example, the wire guide comprises K88 copper, which is a metal alloy of copper that is harder than typical copper used in for bond wires. The wire guide 204 may alternatively be formed of or comprise other materials with a higher material hardness than the bond wire 108, e.g., diamond, sapphire, etc. Additionally, the wire guide 204 is formed with a high stiffness. Stiffness refers to the propensity of the wire guide 204 to return to its original position after being subjected to a high force. In this case, the wire guide 204 may have a sufficiently high stiffness to perform the wire bonding process disclosed herein with a bond wire 108, e.g., a copper bond wire at least 500 μm in diameter, and return to its original position with negligible bending or warpage. This high stiffness is obtained through a combination of using high material harness materials as disclosed above and through appropriate dimensioning and configuration of the bond wedge 202.

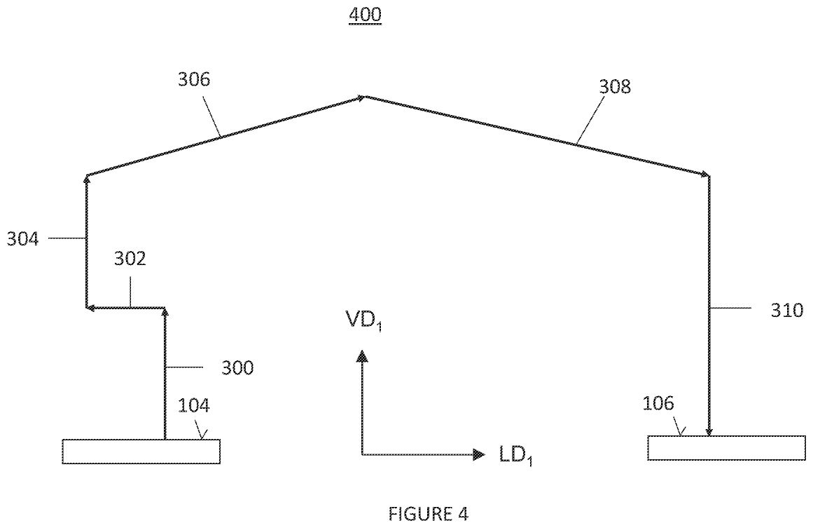

Referring to the combination of FIGS. 1 and 2, the wire bonder 200 forms the wire bond loop 102 in the following way. Initially, the bond wire 108 is bonded to the first bonding surface 104 using the bond wedge 202. This process may involve applying pressure to the bond wire 108 by the tip 206 of the bond wedge 202 in a vertical direction that is orthogonal to the first bonding surface 104. Optionally, ultrasonic energy may be applied to the bond wire 108 and/or to the first bonding surface 104 while the pressure is applied, thereby deforming the bond wire 108 and creating a permanent substance-to-substance bond between the bond wire 108 and the first bonding surface 104. Additionally, or alternatively, heat may be applied to the bond wire 108 and/or the first bonding surface 104, thereby softening the bond wire 108 and/or the metal that forms the first bonding surface 104 before. The heat may be applied before, during, or after the application of pressure by the bond wedge 202. After the bond between the bond wire 108 and the first bonding surface 104 is created, the bond wedge 202 is moved in a loop pattern whereby the bond wire 108 passes through the wire guide 204. The loop pattern moves the bond wedge 202 in open-ended shape (e.g., as shown in FIG. 4) between the first bonding surface 104 and the second bonding surface 106. After moving the bond wire 108 in the loop pattern, the bond wire 108 is bonded to the second bonding surface 106 using the bond wedge 202, e.g., in the same way as the process for bonding the bond wire 108 to the first bonding surface 104.

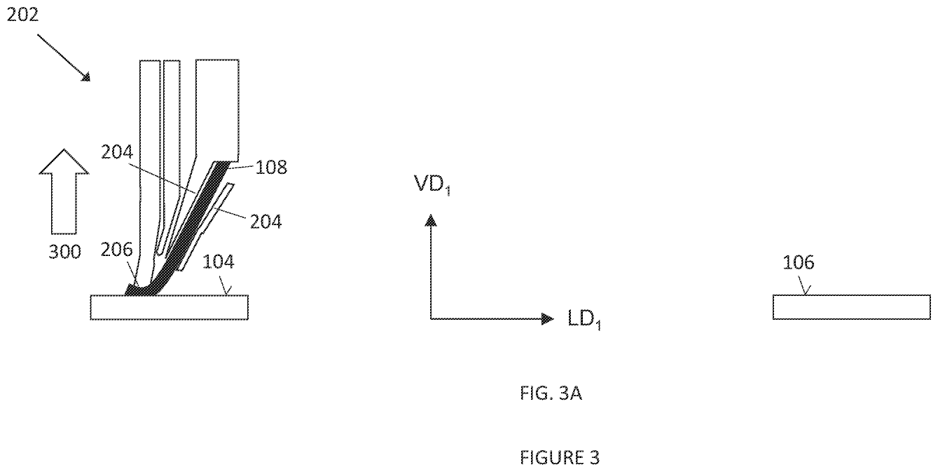

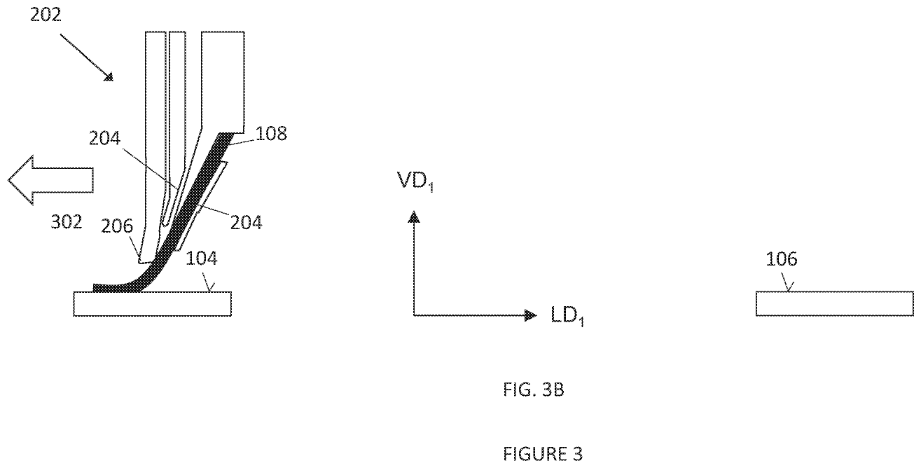

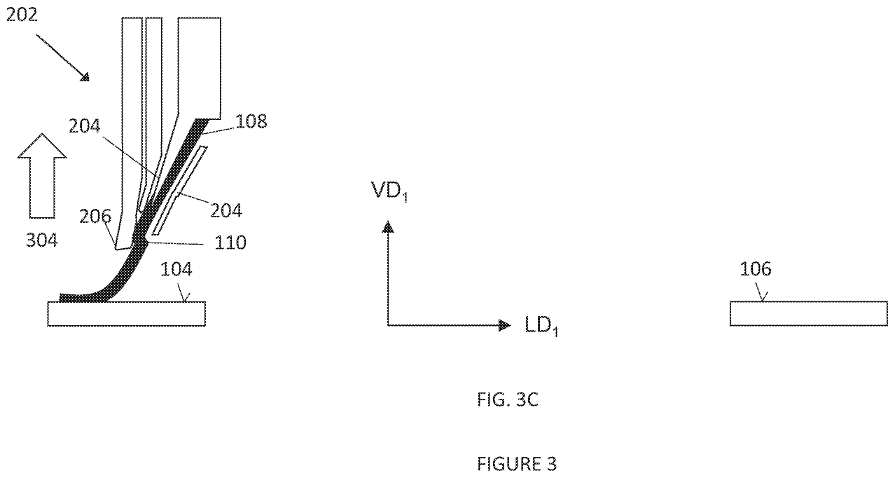

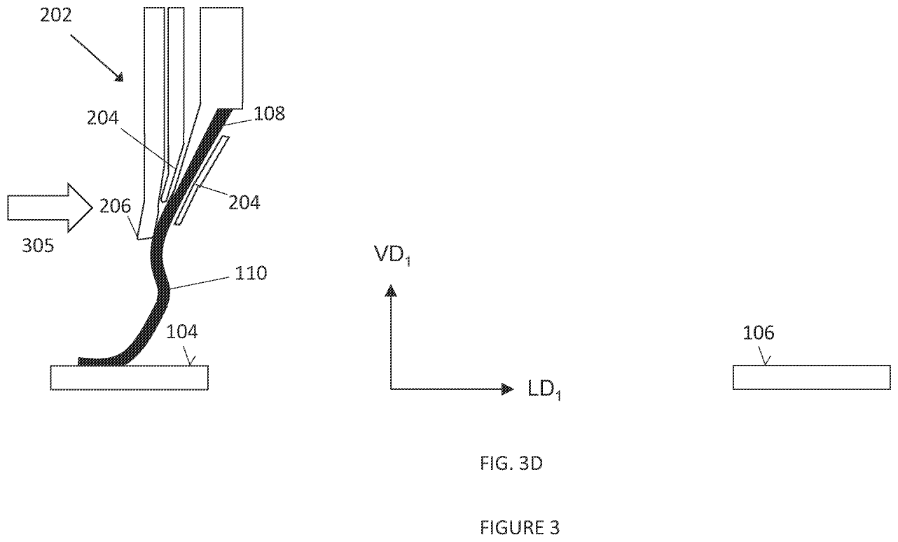

Referring to FIG. 3, the method of forming the bond wire connection 100 is shown at selected points in the loop pattern. As shown in FIG. 3A, the loop pattern comprises a first movement 300 immediately after bonding the bond wire 108 to the first bonding surface 104. The first movement 300 moves the bond wedge 202 vertically away from the first bonding surface 104. According to an embodiment, the first movement 300 moves the bond wedge 202 in a vertical direction VD₁ that is orthogonal to the first bonding surface 104. Alternatively, the first movement 300 may comprise lateral movement as well, e.g., the first movement 300 may move the bond wedge 202 vertically away from the first bonding surface 104 while also moving the bond wedge 202 in a lateral direction LD₁ towards the second bonding surface 106.

As shown in FIG. 3B, the loop pattern comprises a second movement 302 that is performed after the first movement 300. The second movement 302 is a retrograde movement whereby the bond wedge 202 moves away from the second bonding surface 106. That is, the bond wedge 202 is moved in an opposite direction as the lateral direction LD₁ that it needs to move in order to reach the second bonding surface 106. According to an embodiment, the retrograde movement moves the bond wedge 202 exclusively in a lateral direction that is substantially parallel to the first bonding surface 104, i.e., substantially orthogonal to the vertical direction VD₁ and opposite from the lateral direction LD₁ shown in the figures. In this context, the term substantially parallel refers to a movement that is nominally parallel and or within +/−5 degrees of parallel. Alternatively, the retrograde movement may comprise a vertical movement component, i.e., the retrograde movement may be intentionally tilted at an angle such that the bond wedge 202 moves vertically towards or away from towards or away from the first bonding surface 104 in the vertical direction VD₁ as it moves laterally away from the second bonding surface 106.

As shown in FIG. 30, the loop pattern comprises a third movement 304 that is performed after the second movement 302. The third movement 304 moves the bond wedge 202 away from the first bonding surface 104. According to an embodiment, the third movement 304 moves the bond wedge 202 in the vertical direction VD₁ that is orthogonal to the first bonding surface 104. Alternatively, the third movement 304 may comprise a lateral movement as well, e.g., the third movement 304 may move the bond wedge 202 vertically away from the first bonding surface 104 while also moving the bond wedge 202 in a lateral direction LD₁ towards the second bonding surface 106.

As shown in FIG. 3D, the loop pattern comprises a further movement 305 that moves the bond wedge 202 laterally towards the second bonding surface 106 immediately after the third movement 304. This further movement may comprise moving the bond wedge 202 in the lateral direction LD₁ that is substantially parallel to the first bonding surface 104. Alternatively, this further movement may comprise vertical movement as well, e.g., the further movement may move the bond wedge 202 vertically towards or away from the first bonding surface 104 while also moving the bond wedge 202 towards the second bonding surface 106 in the lateral direction LD₁.

Referring to FIG. 4, an exemplary loop pattern 400 that may be programmed into a wire bonding machine is shown, according to an embodiment. The loop pattern 400 corresponds to a programmed route that the bond wedge 202 follows in between bonding the bond wire 108 to the first bonding surface 104 and bonding the bond wire 108 to the second bonding surface 106. The loop pattern 400 comprises a first movement 300 performed immediately after bonding the bond wire 108 to the first bonding surface 104, a second movement 302 performed immediately after the first movement 300, a third movement 304 performed immediately after the second movement 302, a fourth movement 306 performed immediately after the third movement 304, a fifth movement 308 performed immediately after the fourth movement 306, and a sixth movement 310 performed immediately after the fifth movement 308 and immediately before bonding the bond wire 108 to the second bonding surface 106. The first movement 300, the second movement 302, and the third movement 304 are performed as described above. In this case, the first movement 300 and the third movement 304 each move the wire bonder 200 exclusively in the vertical direction VD₁ that is orthogonal to the first surface, and the second movement 302 is a retrograde movement that moves the wire bonder 200 exclusively in a direction that is parallel to the first bonding surface 104 and opposite from the lateral direction LD₁. The fourth movement 306 moves the wire bonder 200 in a tilted direction that moves vertically away from the first bonding surface 104 and laterally towards the second bonding surface 106 the lateral direction LD₁. The fifth movement 308 moves the wire bonder 200 in a tilted direction that moves vertically towards the first bonding surface 104 and laterally towards the second bonding surface 106 the lateral direction LD₁. Thus, the fourth and fifth movements 306, 308 form an arched pattern with an apex point in between the first bonding surface 104 and the second bonding surface 106. The sixth movement 310 moves the bond wedge 202 vertically towards the second surface, thereby bringing the bond wedge 202 vertically to a location wherein the bond wedge 202 bond wedge may effectuate the bond between the bond wire 108 and the second bonding surface 106.

Referring again to FIG. 1, the wire bond loop 102 is characterized by two dimensional parameters, namely, a height H₁ of the wire bond loop 102 and a length L₁ of the wire bond loop 102. The height H₁ of the wire bond loop 102 refers to a maximum displacement between an apex point of the wire bond loop 102 and the furthest one of the first bonding surface 104 and the second bonding surface 106. The length L₁ of the wire bond loop 102 refers to a distance between the contacting point of the wire bond loop 102 and the first bonding surface 104 and the contacting point of the wire bond loop 102 and the second bonding surface 106. The length L₁ of the wire bond loop 102 includes a part of the bond wire 108 that contacts the metal surface. In the case of multiple wire bond loops 102 formed in succession, the length L₁ of the wire bond loops 102 may be measured at the midpoint of the contacting portion of the bond wire 108.

The ratio between the height H₁ of the wire bond loop 102 and the length L₁ of the wire bond loop 102 is an important parameter that impacts cost and performance of the bond wire connection 100. By reducing the height H₁ of the wire bond loop 102 at a given length L₁, the electrical resistance of the connection may be reduced and the material costs for forming the bond wire connection 100 may be reduced. When compounded across a device with tens, hundreds or even thousands of these wire bond loops 102, the benefits of such a height reduction may be significant. Current wire bonding technologies are limited in their ability to lower the height H₁ of a wire bond loop 102. Moreover, there is an inverse relationship between the length L₁ of the wire bond loop 102 and the lowest achievable height H₁ of the wire bond loop 102. That is, shorter wire bond loops 102 may require a higher wire bond loop 102 height H₁ in order to ensure that the bond wire 108 deviates from the bonding plane and does not cause an electrical short. Using a copper bond wire 108 with a diameter of 400 μm as an example, the minimum achievable height H₁ of the wire bond which enables a stable loop shaping by a conventional wire bonding technique is 2000 μm for a wire bond length L₁ of 5,500 μm, is 2,200 μm for a wire bond length L₁ of 5,000 μm, is 2,400 μm for a wire bond length L₁ of 4,500 μm, is 2,800 μm for a wire bond length L₁ of 4,000 μm, is 3,000 μm for a wire bond length L₁ of 3,500 μm, and is 3,500 μm for a wire bond length L₁ of 3,000 μm. In this context, a conventional wire bonding technique refers to a technique wherein the bond wedge 202 does not move in a retrograde movement and/or does not use a wire guide 204 with a high stiffness that is formed from a material with a higher material hardness than the bond wire.

The combination of moving the bond wedge 202 in a loop pattern that comprises a retrograde movement and using a wire guide with a high stiffness that is formed from a material with a higher material hardness than the bond wire 108 allows for the formation of wire bond loops 102 with a significantly lower ratio between the height H₁ of the wire bond loop 102 and the length L₁ of the wire bond loop 102 than the conventional wire bonding technique. Table 1 below provides exemplary values for the height H₁ of the wire bond loop 102 and the length L₁ of the wire bond loop 102 that may be obtained in a copper bond wire 108 with a diameter of 400 μm according to the presently disclosed techniques.

TABLE 1

| Bond Loop Length (μm) | Bond Loop Height (μm) |
|---|---|
| 5,500 | ≤1,200 ≥ 1,800 |
| 5,000 | ≤1,200 ≥ 2,000 |
| 4,500 | ≤1,200 ≥ 2,200 |
| 4,000 | ≤1,200 ≥ 2,600 |
| 3,500 | ≤1,200 ≥ 2,800 |
| 3,000 | ≤1,200 ≥ 3,000 |

The above provided values are illustrative of a beneficial ratio between the height H₁ of the wire bond loop 102 and the length L₁ of the wire bond loop 102 that may be obtained by the presently disclosed technique. An equivalent beneficial improvement to the ratio may be obtained with different types of bond wires 108, e.g., bond wires 108 having different thickness, hardness, material composition, etc., while not necessarily having the same absolute values as provided above.

Referring again to FIG. 3, the beneficial improvement to the ratio between the height H₁ of the wire bond loop 102 and the length L₁ of the wire bond loop 102 may result from a manipulation of the bond wire 108 that occurs during the movement of the bond wedge 202 in the loop pattern 400. Specifically referring to FIGS. 3C-3D, the retrograde movement of the bond wedge 202 creates a kink 110 in the bond wire 108, i.e., an acute curving of the bond wire 108 away from the second bonding surface 106. This kink 110 remains in the bond wire 108 as the wire bonder 200 continues forming the wire bond loop 102 by moving towards the second bonding surface 106. This kink 110 facilitates the reliable formation of low-profile wire bond loops 102 by instilling the necessary vertical clearance between the bond wire 108 and the first bonding surface 104 into the wire bond loop 102 and providing a weaker point that allows for greater manipulation of the wire bond loop 102. The subsequent movement of the bond wedge 202 towards the second bonding surface 106 therefore does not result in creating too shallow of a departure angle. The kink 110 results from the combination of moving the bond wedge 202 in the retrograde movement and using a wire guide 204 with a high stiffness that is formed from a material with a higher material hardness than the bond wire 108. This allows the wire guide 204 to instill the kink 110 as a permanent shape without damage or excessive wear to the wire guide 204. By way of comparison, a bond wedge 202 with a relatively softer material, e.g., plastic, for the wire guide 204 may not be able to effectively create the kink and/or may become damaged by an acute retrograde movement when used in combination with a harder bond wire 108.

The loop pattern 400 described with reference to FIG. 4 was used in combination with a 400 μm thick copper bond wire 108, with bond loop lengths L₁ in the range of 2,000 μm to 15,000 μm. The second movement 302 of the loop pattern 400, i.e., the retrograde movement, moves the bond wedge 202 by up to 600 μm. This loop pattern 400 may represent an at least nearly optimized pattern for this particular wire type. The optimal geometry and extent of retrograde movement may differ in the case of different bond wire 108s. In general, a beneficial impact on the length L₁ to width ratio of a wire bond loop 102 may be realized by any loop pattern 400 that comprises a retrograde movement and utilizes a wire guide 204 with a high stiffness that is formed from a material with a higher material hardness than the bond wire 108.

Although the present disclosure is not so limited, the following numbered examples demonstrate one or more aspects of the disclosure.

Example 1. A method of forming a bond wire connection, the method comprising: providing a wire bonder comprising a bond wedge with a wire guide; and forming a wire bond loop by initially bonding a bond wire to a first bonding surface using the bond wedge, then moving the wire bonder in a loop pattern whereby the bond wire passes through the wire guide, and then bonding the bond wire to a second bonding surface using the bond wedge, wherein moving the wire bonder in the loop pattern comprises a retrograde movement whereby the wire bonder moves away from the second bonding surface, and wherein the wire guide is formed from a material with a higher material hardness than the bond wire.

Example 2. The method of example 1, wherein the loop pattern comprises a first movement immediately after bonding the bond wire to the first bonding surface and a second movement immediately after the first movement, wherein the first movement moves the bond wedge vertically away from the first bonding surface, and wherein the second movement is the retrograde movement.

Example 3. The method of example 2, wherein the retrograde movement moves the wire bonder in a lateral direction that is substantially parallel to the first bonding surface.

Example 4. The method of example 2, wherein the loop pattern comprises a third movement immediately after the second movement, and wherein the third movement moves the wire bonder vertically away from the first bonding surface.

Example 5. The method of example 4, wherein the loop pattern moves the wire bonder laterally towards the second bonding surface immediately after the third movement.

Example 6. The method of example 5, wherein the loop pattern comprises a fourth movement immediately after the third movement and a fifth movement immediately after the fourth movement, wherein the fourth movement moves the wire bonder in a tilted direction that moves vertically away from the first bonding surface and laterally towards the second bonding surface, and wherein the fifth movement moves the wire bonder in a tilted direction that moves vertically towards from the first bonding surface and laterally towards the second bonding surface.

Example 7. The method of example 1, wherein the bond wire is a copper or copper alloy wire, and wherein the wire guide is formed from a metal with a higher material hardness than the copper or copper alloy wire.

Example 8. The method of example 7, wherein the wire guide comprises any one or more of: Cu, Ni, TI, Zn, Fe, and alloys thereof.

Example 9. The method of example 1, wherein the bond wire is a copper or copper alloy wire with a diameter of between 300 μm and 500 μm.

Example 10. The method of example 9, wherein the diameter of the bond wire is 400 μm.

Example 11. The method of example 10, wherein a bond loop length of the wire bond loop is ≤5,500 μm, and wherein a bond loop height of the wire bond loop is ≤1,800 μm.

Example 12. The method of example 11, wherein the bond loop length of the wire bond loop is ≤4,000 μm.

Example 13. The method of example 11, wherein the bond loop height of the wire bond loop is ≤1,400 μm.

Example 14. A semiconductor device, comprising: a bond wire connection that forms an electrical connection of a semiconductor device, wherein the bond wire connection comprises a wire bond loop between a first bonding surface and a second bonding surface, wherein the bond wire is a copper or copper alloy wire with a diameter of between 300 μm and 500 μm, wherein a bond loop height of the wire bond loop is between 1,200 μm and 2,200.

Example 15. The semiconductor device of claim 14, wherein the bond loop height is less than or equal to 2,000 μm.

Example 16. The semiconductor device of example 15, wherein the bond loop height is less than or equal to 1,400 μm.

Example 17. The semiconductor device of example 14, wherein a bond loop length of the wire bond loop is between 3,500 μm and 6,000 μm.

Example 18. The semiconductor device of example 17, wherein the bond loop length is less than 5,000 μm.

Example 19. The semiconductor device of example 18, wherein the bond loop length is less than 4,000 μm.

Example 20. The semiconductor device of example 14, wherein the bond wire is a copper wire, and wherein the diameter is 400 μm.

Spatially relative terms such as “under,” “below,” “lower,” “over,” “upper,” “main”, “rear”, and the like, are used for ease of description to explain the positioning of one element relative to a second element. These terms are intended to encompass different orientations of the device in addition to different orientations than those depicted in the figures. Further, terms such as “first,” “second,” and the like, are also used to describe various elements, regions, sections, etc. and are also not intended to be limiting. Like terms refer to like elements throughout the description.

As used herein, the terms “having,” “containing,” “including,” “comprising” and the like are open-ended terms that indicate the presence of stated elements or features, but do not preclude additional elements or features. The articles “a,” “an” and “the” are intended to include the plural as well as the singular, unless the context clearly indicates otherwise.

It is to be understood that the features of the various embodiments described herein may be combined with each other, unless specifically noted otherwise.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A method of forming a bond wire connection, the method comprising:
providing a wire bonder comprising a bond wedge with a wire guide; and
forming a wire bond loop by initially bonding a bond wire to a first bonding surface using the bond wedge, then moving the bond wedge in a loop pattern whereby the bond wire passes through the wire guide, and then bonding the bond wire to a second bonding surface using the bond wedge,
wherein moving the bond wedge in the loop pattern comprises a retrograde movement whereby the bond wedge moves away from the second bonding surface, and
wherein the wire guide is formed from a material with a higher material hardness than the bond wire.

2. The method of claim 1, wherein the loop pattern comprises a first movement immediately after bonding the bond wire to the first bonding surface and a second movement immediately after the first movement, wherein the first movement moves the bond wedge vertically away from the first bonding surface, and wherein the second movement is the retrograde movement.

3. The method of claim 2, wherein the retrograde movement moves the wire bonder in a lateral direction that is substantially parallel to the first bonding surface.

4. The method of claim 2, wherein the loop pattern comprises a third movement immediately after the second movement, and wherein the third movement moves the wire bonder vertically away from the first bonding surface.

5. The method of claim 4, wherein the loop pattern moves the bond wedge laterally towards the second bonding surface immediately after the third movement.

6. The method of claim 5, wherein the loop pattern comprises a fourth movement immediately after the third movement and a fifth movement immediately after the fourth movement, wherein the fourth movement moves the bond wedge in a tilted direction that moves vertically away from the first bonding surface and laterally towards the second bonding surface, and wherein the fifth movement moves the bond wedge in a tilted direction that moves vertically towards from the first bonding surface and laterally towards the second bonding surface.

7. The method of claim 1, wherein the bond wire is a copper or copper alloy wire, and wherein the wire guide is formed from a metal with a higher material hardness than the copper or copper alloy wire.

8. The method of claim 7, wherein the wire guide comprises any one or more of: Cu, Ni, Ti, Zn, Fe, and alloys thereof.

9. The method of claim 1, wherein the bond wire is a copper or copper alloy wire with a diameter of between 300 μm and 500 μm.

10. The method of claim 9, wherein the diameter of the bond wire is 400 μm.

11. The method of claim 10, wherein a bond loop length of the wire bond loop is ≤5,500 μm, and wherein a bond loop height of the wire bond loop is ≤1,800 μm.

12. The method of claim 11, wherein the bond loop length of the wire bond loop is ≤4,000 μm.

13. The method of claim 11, wherein the bond loop height of the wire bond loop is ≤1,400 μm.

14. A semiconductor device, comprising:
a bond wire connection that forms an electrical connection of a semiconductor device,
wherein the bond wire connection comprises a wire bond loop between a first bonding surface and a second bonding surface,
wherein the wire bond loop is formed from a bond wire comprising copper with a diameter of between 300 μm and 500 μm, and
wherein a bond loop height of the wire bond loop is between 1,200 μm and 2,200.

15. The semiconductor device of claim 14, wherein the bond loop height is less than or equal to 2,000 μm.

16. The semiconductor device of claim 15, wherein the bond loop height is less than or equal to 1,400 μm.

17. The semiconductor device of claim 14, wherein a bond loop length of the wire bond loop is between 3,500 μm and 6,000 μm.

18. The semiconductor device of claim 17, wherein the bond loop length is less than 5,000 μm.

19. The semiconductor device of claim 18, wherein the bond loop length is less than 4,000 μm.

20. The semiconductor device of claim 14, wherein the bond wire is a copper wire, and wherein the diameter is 400 μm.
